(19) United States
(12) Patent Application Publication
(10) Pub. No.: US 2024/0271282 A1
(43) Pub. Date: Aug. 15, 2024

(54) SOURCE GAS NOZZLE AND SEMICONDUCTOR WAFER PROCESSING APPARATUS INCLUDING THE SAME

(71) Applicant: SUMSUNG ELECTRONICS CO., LTD., SUWON-SI (KR)

(72) Inventors: Sang Yup Lee, SUWON-SI (KR); Sebin Choi, SUWON-SI (KR); Jiye Park, SUWON-SI (KR); Byeongho Hwang, SUWON-SI (KR); Sunghyup Kim, SUWON-SI (KR); Taeheung Ahn, SUWON-SI (KR)

(21) Appl. No.: 18/505,057

(22) Filed: Nov. 8, 2023

(30) Foreign Application Priority Data
Feb. 10, 2023 (KR) 10-2023-0018157

(51) Int. Cl. C23C 16/455

(52) U.S. Cl. CPC C23C 16/45578

(57) ABSTRACT

A source gas nozzle including: an upstream pipe; a downstream pipe; and a U-turn pipe connecting the upstream pipe and the downstream pipe, wherein a plurality of first gas discharge holes are disposed in a longitudinal direction along at least one of the upstream pipe or the downstream pipe, and a gas non-discharge hole region and an asymmetric gas discharge hole region comprising a plurality of second gas discharge holes are disposed in opposite ones of the upstream pipe and the downstream pipe, and wherein the gas non-discharge hole region and the asymmetric gas discharge hole region are adjacent.

### CROSS-REFERENCE TO RELATED APPLICATION

This application claims priority under 35 U.S.C. § 119 to Korean Patent Application No. 10-2023-0018157, filed on Feb. 10, 2023, with the Korean Intellectual Property Office, the inventive concept of which is herein incorporated by reference.

### TECHNICAL FIELD

The present inventive concept relates to a source gas nozzle and a semiconductor wafer processing apparatus including the same.

### DESCRIPTION OF RELATED ART

Typically, a semiconductor manufacturing process includes a series of sub-processes. These sub-processes may include a deposition process, a photo process, an etching process, an ion implantation process, and the like. Some of these sub-processes (e.g., the deposition process, a diffusion process, and the like) may be performed in a vacuum reaction chamber (also referred to as a “tube”) and with the use of a semiconductor wafer processing apparatus. The semiconductor wafer processing apparatus may be, for example, a chemical vapor deposition (CVD) device, an atomic layer deposition (ALD) device, or a diffusion furnace.

In particular, an atomic layer deposition process may include spraying a gas through holes in a nozzle, where one or more of the holes may be aligned to a wafer in the vacuum reaction chamber. In the atomic layer deposition process, an amount of the gas sprayed from each hole may be a factor in determining a thickness of a deposition layer formed on the wafers.

It can be difficult to achieve a uniform flow rate from all of the holes of the nozzle. In the case of an upper U-turn nozzle, a flow rate may become slower as a distance from a gas inlet increases, so a flow rate of a gas sprayed from a hole away from the gas inlet may be low and the uniformity of the deposition layer formed on the wafers along a length of the nozzle may be decreased. In some cases, a number of dummy wafers may be disposed in the reaction tube to achieve a uniform deposition layer thickness. However, the use of dummy wafers lowers a number of wafers manufactured per batch.

### SUMMARY

An aspect of the present disclosure is to provide a source gas nozzle having different gas flow rates in different regions corresponding to different wafers in a reaction tube.

Another aspect of the present disclosure is to provide a source gas nozzle capable forming a deposition layer having a uniform thickness on a plurality of wafers by controlling a flow rate of a source gas toward the wafers and controlling a spraying amount of the source gas.

Another aspect of the present disclosure is to provide a semiconductor wafer processing apparatus having an improved source gas nozzle for forming a deposition layer having a uniform thickness on a wafer and improving productivity of wafers per batch.

According to an aspect of the present disclosure, a source gas nozzle includes: an upstream pipe; a downstream pipe; and a U-turn pipe connecting the upstream pipe and the downstream pipe, wherein a plurality of first gas discharge holes may be disposed in a longitudinal direction along at least one of the upstream pipe or the downstream pipe, and a gas non-discharge hole region and an asymmetric gas discharge hole region comprising a plurality of second gas discharge holes may be disposed in opposite ones of the upstream pipe or the downstream pipe, and wherein the gas non-discharge hole region and the asymmetric gas discharge hole region are adjacent.

According to another aspect of the present disclosure, a semiconductor wafer processing apparatus, may include: a reaction tube in which a plurality of wafers are loaded; a gas supply pipe supplying a source gas to the reaction tube; and a source gas nozzle disposed in the reaction tube and receiving the source gas from the gas supply pipe and spraying the source gas into the reaction tube; wherein the source gas nozzle may include an upstream pipe; a downstream pipe; and a U-turn pipe connecting the upstream pipe and the downstream pipe, wherein a plurality of gas discharge holes are disposed in the source gas nozzle along the upstream pipe and the downstream pipe in an asymmetric arrangement wherein a same number of gas discharge holes of the plurality of gas discharge holes correspond to each wafer of the plurality of wafers, and wherein at least one of the upstream pipe or the downstream pipe comprises a gas non-discharge hole region and the plurality of gas discharge holes are disposed outside of the gas non-discharge hole region.

According to another aspect of the present disclosure, a semiconductor wafer processing apparatus may include: a reaction tube; a gas supply pipe supplying a source gas to the reaction tube; and a source gas nozzle disposed in the reaction tube and receiving gas from the gas supply pipe and spraying the source gas into the reaction tube, wherein the source gas nozzle may include: an upstream pipe; a downstream pipe; and a U-turn pipe connecting the upstream pipe and the downstream pipe, wherein a plurality of first gas discharge holes may be formed in a longitudinal direction in at least one of the upstream pipe or the downstream pipe, wherein a gas non-discharge hole region in which the plurality of first gas discharge holes are not formed and an asymmetric gas discharge hole region comprising a plurality of second gas discharge holes may be disposed in opposite ones of the upstream pipe and the downstream pipe, and wherein the gas non-discharge hole region and the asymmetric gas discharge hole region may be adjacent.

### BRIEF DESCRIPTION OF DRAWINGS

The above and other aspects, features, and advantages of the present inventive concept will be more clearly understood from the following detailed description taken in conjunction with the accompanying drawings, in which:

FIG. 1 is a perspective view schematically illustrating a semiconductor wafer processing apparatus according to an example of the present disclosure.

FIG. 2 is a schematic cross-sectional view of a semiconductor wafer processing apparatus according to an example of the present disclosure.

FIG. 3 is across-sectional view taken in direction A-A of FIG. 2.

FIG. 4 is a schematic diagram of an embodiment of a source gas nozzle according to an example of the present disclosure.

FIG. 5 is a schematic diagram of an embodiment of a source gas nozzle according to an example of the present disclosure.

FIG. 6 is a schematic diagram of an embodiment of a source gas nozzle according to an example of the present disclosure.

FIG. 7 is a schematic diagram of an embodiment of a source gas nozzle according to an example of the present disclosure.

FIG. 8 is a schematic diagram of an embodiment of a source gas nozzle according to an example of the present disclosure.

FIG. 9 is a schematic diagram of an embodiment of a source gas nozzle according to an example of the present disclosure.

FIG. 10 is a schematic diagram of an embodiment of a source gas nozzle according to an example of the present disclosure.

FIG. 11 is a schematic diagram of an embodiment of a source gas nozzle according to an example of the present disclosure.

FIG. 12 is a schematic diagram of an embodiment of a source gas nozzle according to an example of the present disclosure.

### DETAILED DESCRIPTION

Hereinafter, example embodiments of the present disclosure will be described with reference to the attached drawings. Example embodiments of the present disclosure may be modified in many different forms. Accordingly, shapes and sizes of elements in the drawings may be exaggerated for clear description, and elements indicated by the same reference numeral are the same elements in the drawings.

In the present disclosure, the meaning of “connection” is a concept including “directly connected” as well as “indirectly connected” through another configuration. Also, in some cases, a “connection” may include a concept including all “electrically connected things.”

In the present disclosure, expressions such as “first” and “second” are used to distinguish one component from another, and do not limit the order and/or importance of the components. In some cases, without departing from the scope of rights, a first element may be referred to as a second element, and similarly, a second element may also be referred to as a first element.

Terms used in this disclosure are only used to describe an example, and are not intended to limit the disclosure. In this case, singular expressions include plural expressions unless the context clearly indicates otherwise.

### Semiconductor Wafer Processing Apparatus

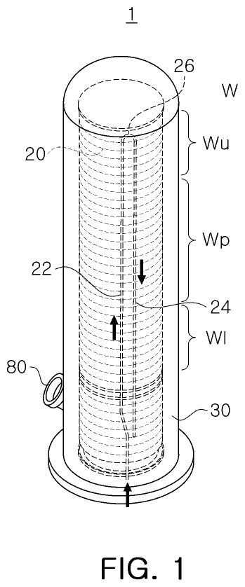

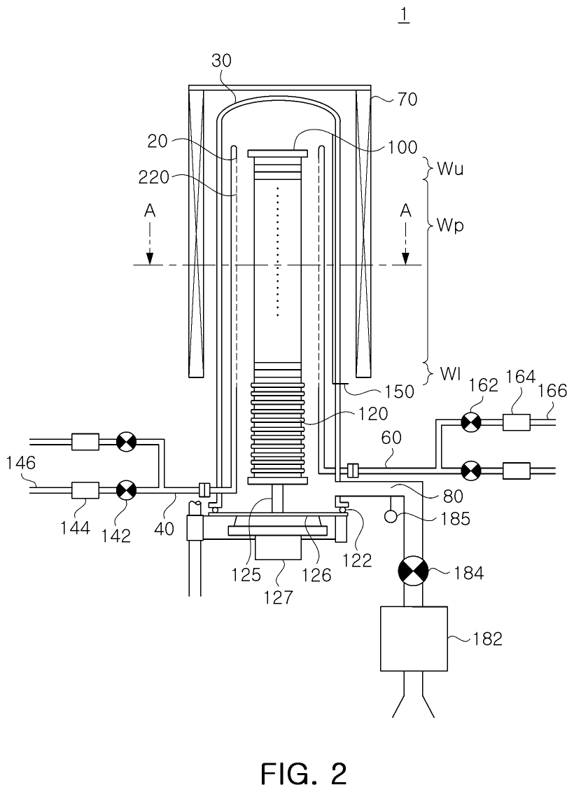

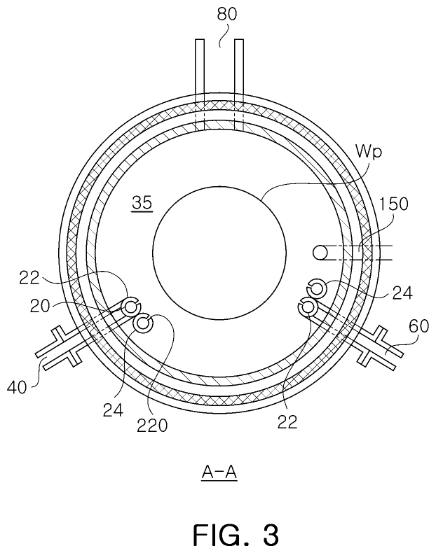

FIG. 1 is a perspective view schematically illustrating a semiconductor wafer processing apparatus according to an example of the present disclosure. FIG. 2 is a cross-sectional view schematically illustrating a semiconductor wafer processing apparatus according to an example of the present disclosure. FIG. 3 is a cross-sectional view taken in a direction A-A of FIG. 2.

Referring to FIGS. 1 to 3, a semiconductor wafer processing apparatus 1 may include a reaction tube 30, gas supply pipes 40 and 60, a source gas nozzle 20, and the like.

A plurality of wafers W may be loaded and disposed in the reaction tube 30 of the semiconductor wafer processing apparatus 1. The reaction tube 30 may be formed of a heat-resistant material. For example, the reaction tube 30 may be formed of a material such as quartz (SiC₂), silicon (SiC), or the like. The reaction tube 30 may have a cylindrical shape having a closed upper end and an open lower end. A lower end of the reaction tube 30 may have an airtight connection. For example, the lower end of the reaction tube 30 may be made airtight by being in contact with a seal cap 126 and an O-ring 122. The O-ring 122 may be installed as an airtight member between the reaction tube 30 and the seal cap 126. Here, the seal cap 126 may be formed of metal such as SUS, or the like. The seal cap 126 may have a disk shape, for example.

The wafers W may include one or more upper dummy wafers Wu, which may be sequentially disposed from an upper portion to a lower portion of the reaction tube 30, a plurality of process wafers Wp, and a plurality of lower dummy wafers W1. For example, in a case that one-hundred and seventeen wafers W are used in one batch of an atomic layer deposition (ALD) process, the wafers W may include six upper dummy wafers Wu and six lower dummy wafers W1. The number of wafers W is not limited, and may be variously changed.

A wafer boat 100 in the reaction tube 30 may protect and hold the wafers W. In a batch process, the plurality of wafers W may be supported by the wafer boat 100 and may be individually disposed at intervals in a vertical direction while being held in a horizontal position. The plurality of wafers W may be centered on each other in the vertical direction. The wafer boat 100 is manufactured using a heat-resistant material such as quartz or SiC, for example.

A rotating mechanism 127 for rotating the wafer boat 100 may be installed below the seal cap 126. The rotating mechanism 127 may face a reaction chamber inside the reaction tube 30. A rotation shaft 125 of the rotating mechanism 127 may penetrate through the seal cap 126 and may be connected to the wafer boat 100. The rotating mechanism 127 may rotate the wafer boat 100, thereby rotating the plurality of wafers W. The rotating mechanism 127 may be raised and lowered to carry the wafer boat 100 into or out of the reaction tube 30.

The semiconductor wafer processing apparatus 1 may include a heater 70. The heater 70 may be used for achieving temperature control around an outer peripheral portion of the reaction tube 30. The heater 70 may have a cylindrical shape and may be installed around the reaction tube 30. The heater 70 may serve to excite a fuel gas in the reaction tube 30.

A temperature sensor 150 for detecting a temperature may be installed in the reaction tube 30. By adjusting an energization state of the heater 70 based on temperature information detected by the temperature sensor 150, a temperature of a reaction chamber in the reaction tube 30 may be adjusted to a desired temperature.

A plurality of source gas nozzles 20 may be disposed in the reaction tube 30, and each of the source gas nozzles 20 may be connected to gas supply pipes 40 and 60. While two source gas nozzles 20 are disclosed, embodiments are not particularly limited. Mass Flow Controllers (MFC), including MFCs 144 and 164, and open/close valves 142 and 162 may be installed along the gas supply pipes 40 and 60 from inlets 146 and 166. For example, starting at the inlet 146, the MFC 144 and the open/close valve 142 may be installed in sequence along the gas supply pipe 40, and starting at the inlet 166, the MFC 164 and the open/close valve 162 may be installed in sequence along the gas supply pipe 60.

The gas supply pipes 40 and 60 may be connected to the plurality of source gas nozzles 20, and may supply a source gas to the reaction chamber in the reaction tube 30. The source gas may be deposited on the plurality of wafers W. The source gas may include, for example, a halosilane source gas containing silicon (Si) and a halogen element. For example, a carbon-free source gas including Si and chlorine (Cl), that is, an inorganic-based chlorosilane source gas can be used as the halosilane source gas. For example, the inorganic-based chlorosilane source gas may be a hexachlorodisilane (Si₂Cl₆, abbreviation: HCDS) gas, an octachlorotrisilane (Si₃Cl₈) gas, or the like. These gases may act as a Si source in a wafer film formation process.

In addition, a hydrocarbon-based gas may be supplied as a carbon-containing gas serving as a carbon (C) source for film formation through the gas supply pipes 40 and 60. The hydrocarbon-based gas may be, for example, a propylene (C₃H₆) gas.

In addition, an oxygen-containing gas and a hydrogen-containing gas may serve as a reaction gas and may be supplied to the reaction chamber through the gas supply pipes 40 and 60. For example, oxygen (O₂) gas may be supplied as the O-containing gas, and ammonia (NH₃) gas may be supplied as the H-containing gas.

In addition, a gas such as an inert gas, or the like, may be supplied in a deposition process through the gas supply pipes 40 and 60. All of these source gases, reactive gases, inert gases, and the like may be collectively referred to as source gases.

The semiconductor wafer processing apparatus 1 may include an exhaust pipe 80 for exhausting gas from the reaction chamber. The reaction tube 30 may be connected to the exhaust pipe 80, and may be used for exhausting gas from the reaction chamber. A pressure sensor 185 for sensing the pressure in the reaction chamber and an automatic pressure control valve 184 (Auto Pressure Valve) may be provided along the exhaust pipe 80. For example, the pressure sensor 185 and the automatic pressure control valve 184 may be sequentially provided along the exhaust pipe 80. In addition, a vacuum pump 182 may be connected to the exhaust pipe 80. For example, the vacuum pump 182 may be connected to the exhaust pipe 80 downstream from the automatic pressure control valve 184. The pressure sensor 185, the automatic pressure control valve 184, and the vacuum pump 182 connected along the exhaust pipe 80 may form an exhaust system of the semiconductor wafer processing apparatus 1.

### Source Gas Nozzle

The source gas nozzle 20 may be installed in an annular space between an inner wall of the reaction tube 30 and the wafer boat 100 in a longitudinal direction from a lower portion of the inner wall of the reaction tube 30 to an upper portion of the inner wall. The source gas nozzle 20 may be installed on a side of an outer circumferential surface of the wafer boat 100 carried into the reaction tube 30, which may be perpendicular to a surface of the wafer W. In a case where the wafer boat 100 is loaded with wafers W, the source gas nozzle 20 may be installed on a side of an outer circumferential surface of the wafers W carried into the reaction tube 30 by the wafer boat 100. A gas discharge hole 220 may be formed in the source gas nozzle 20. The gas discharge hole 220 may receive a source gas and supply the source gas toward a center of the wafer boat 100, which may support the wafers W. A main flow of gas through the gas discharge hole 220 may proceed in a horizontal direction, which may be parallel to the surface of the wafers W.

In an embodiment, the gas discharge holes 220 may be disposed along the source gas nozzle 20 in a numeric relationship with the wafers W disposed in the wafer boat 100. For example, the gas discharge holes 220 may be disposed along the source gas nozzle 20 in a one-to-one relationship, a two-to-one relationship, etc., with the wafers W. The source gas may be sprayed from the gas discharge holes 200 and deposited on the wafers W. In a deposition operation, an amount of the source gas sprayed from each hole of the gas discharge holes 200 may be a factor in determining a deposition thickness on the wafers W.

Since the upper portion of the source gas nozzle 20 may be far from the gas supply pipes 40 and 60, a flow rate of the source gas sprayed from the gas discharge hole 220 may be low. When the gas discharge rate of the source gas sprayed from the gas discharge hole 220 becomes slow, the uniformity of deposition on the wafers W may decrease. For example, a difference in a thickness of the source gas deposited on a first wafer and a second wafter may be large.

A method using the source gas nozzle 20 to increase a uniformity of the source gas sprayed onto the wafers W will be described below. The source gas nozzle 20 may include an upstream pipe 22 and a downstream pipe 24. The source gas nozzle 20 may include a U-turn pipe 26 connecting the upstream pipe 22 and the downstream pipe 24. The U-turn pipe 26 may change a direction of the source gas nozzle 20, where a direction of the source gas in the upstream pipe 22 and the direction of the source gas in the downstream pipe 24 may be parallel and opposite one another.

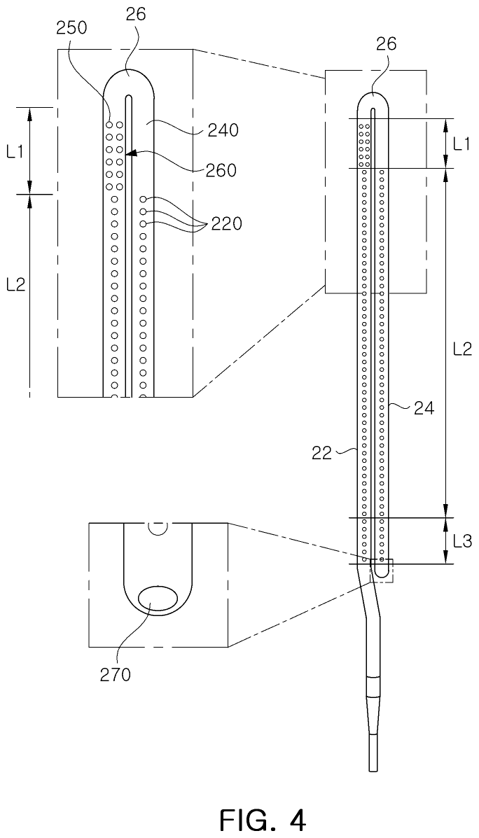

FIG. 4 is a schematic diagram of an embodiment of a source gas nozzle according to an example of the present disclosure.

The source gas nozzle 20 may include an upstream pipe 22, a downstream pipe 24, and a U-turn pipe 26 connecting the upstream pipe 22 and the downstream pipe 24. The upstream pipe 22 and the downstream pipe 24 may be disposed parallel to one another. In the upstream pipe 22, the source gas may flow toward the U-turn pipe 26, and in the downstream pipe 24 the source gas may flow away from the U-turn pipe 26.

First gas discharge holes 220 may be formed in the upstream pipe 22 and the downstream pipe 24 in a longitudinal direction of the source gas nozzle 20. For example, the first gas discharge holes 220 may be formed in a longitudinal direction along the upstream pipe 22 and in a longitudinal direction along the downstream pipe 24. In an embodiment, the first gas discharge holes 220 may be arranged in a row along a length the source gas nozzle 20. The first gas discharge holes 220 may be disposed having a same interval and a same size.

A portion of one of the upstream pipe 22 or the downstream pipe 24 may have a gas non-discharge hole region 240 in which the first gas discharge holes 220 are not formed, such that the plurality of gas discharge holes may be disposed outside of the gas non-discharge hole region. For example, the gas non-discharge hole region 240 may be formed in the downstream pipe 24.

An asymmetric gas discharge hole region 260 comprising a plurality of second gas discharge holes 250 may be disposed in a portion of the upstream pipe 22 corresponding to the gas non-discharge hole region 240. For example, the gas non-discharge hole region 240 may be formed in the downstream pipe 24 and the plurality of second gas discharge holes 250 may be formed in the upstream pipe 22, and the gas non-discharge hole region 240 and the plurality of second gas discharge holes 250 may overlap in a direction perpendicular to the longitudinal directions along the downstream pipe 24 and the upstream pipe 22. In another example, the gas non-discharge hole region 240 and the plurality of second gas discharge holes 250 may be adjacent in the direction perpendicular to the longitudinal directions along opposites ones of the downstream pipe 24 and the upstream pipe 22.

The second gas discharge holes 250 of the asymmetric gas discharge hole region 260 may have a different arrangement, size, or shape than the first gas discharge holes 220. The second gas discharge holes 250 may have at least one of a different arrangement, size, and shape from the first gas discharge holes 220. For example, the second gas discharge holes 250 may include holes of at least two different sizes. The second gas discharge hole 250 may be asymmetrical with respect to the first gas discharge hole 220, and may be disposed in an asymmetric gas discharge hole region 260.

In an embodiment of FIG. 4, the first gas discharge holes 220 may be disposed in a row in a longitudinal direction, and the second gas discharge holes 250 may be located in a first portion L1 below the U-turn pipe 26 and may be disposed in rows in the longitudinal direction. For example, the first gas discharge holes 220 may be arranged in one row along a length the source gas nozzle 20 and the second gas discharge holes 250 may be disposed in two rows in the longitudinal direction along another length the source gas nozzle 20. The present inventive concept is not limited thereto. The first gas discharge holes 220 and the second gas discharge holes 250 may have an asymmetric arrangement along the longitudinal direction along another length the source gas nozzle 20, wherein a same number of gas discharge holes may be disposed corresponding to each wafer W in the wafer boat 100. For example, two gas discharge holes may correspond to each wafer W.

The first portion L1 may correspond to a portion of the reaction tube 30 where the upper dummy wafers Wu may be positioned in relation to the reaction tube 30 of the semiconductor wafer processing apparatus 1. The present inventive concept is not limited thereto.

An end hole 270 may be formed at an end of the downstream pipe 24. The end hole 270 may suppress retention of the source gas in the source gas nozzle 20. The end hole 270 may prevent the source gas supplied to the source gas nozzle 20 from staying inside the source gas nozzle 20. The end hole 270 may be larger than a hole of the first gas discharge holes 220 or the second gas discharge holes 220. In an embodiment, a diameter of the hole of the end hole 270 may be reduced and a plurality of end holes having the reduced diameter may be formed in the source gas nozzle 20.

In the source gas nozzle 20 of an embodiment, the asymmetric gas discharge hole region 260 comprising the second gas discharge holes 250 may be provided in one portion of the upstream pipe 22 corresponding to the gas non-discharge hole region 240 of the downstream pipe 24, and the end hole 270 of the downstream pipe 24 may be provided in the source gas nozzle 20. The end hole 270 of the downstream pipe 24 may be omitted, for example, depending on the type of wafer or processing. The end hole 270 may be applied to any embodiment described herein.

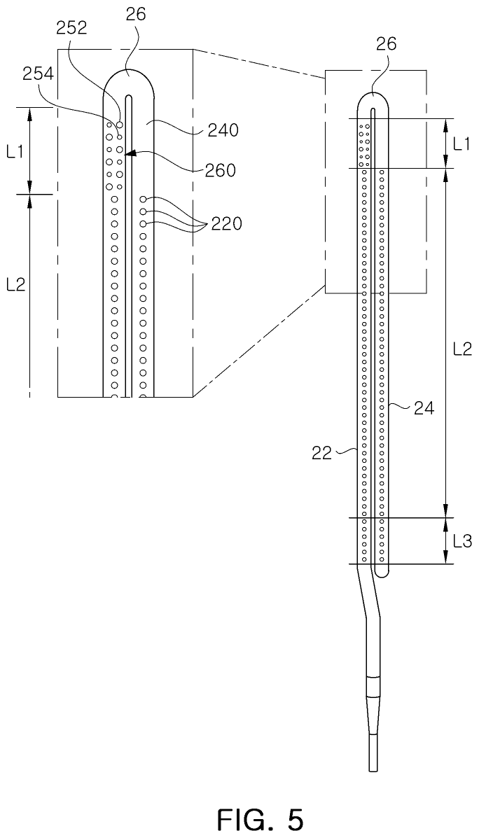

FIG. 5 is a schematic diagram of an embodiment of a source gas nozzle according to an example of the present disclosure.

In an embodiment of FIG. 5, the second gas discharge holes 250 provided in an asymmetric gas discharge hole region 260 may have a first hole 252, larger than the first gas discharge holes 220. In addition, the second gas discharge holes 250 may include a second hole 254, smaller than the first gas discharge holes 220. The first hole 252 and the second hole 254 may be alternately provided in the longitudinal direction. Further, two or more rows of the second gas discharge holes 250, including the first holes 252 and the second holes 254, may be provided in the longitudinal direction.

In an embodiment, the second gas discharge holes 250 provided in an asymmetric gas discharge hole region 260 may include a plurality of first holes 252 larger than the first gas discharge holes 220 and a plurality of second holes 254 smaller than the first gas discharge holes 220, wherein the plurality of first holes 252 and the plurality of second holes 254 are alternately disposed in a matrix. For example, the matrix may include two rows of alternating ones of the plurality of first holes 252 and the plurality of second holes 254, wherein a first row starts with the first hole 252 and a second row starts with the second hole 254 adjacent to the first hole 252.

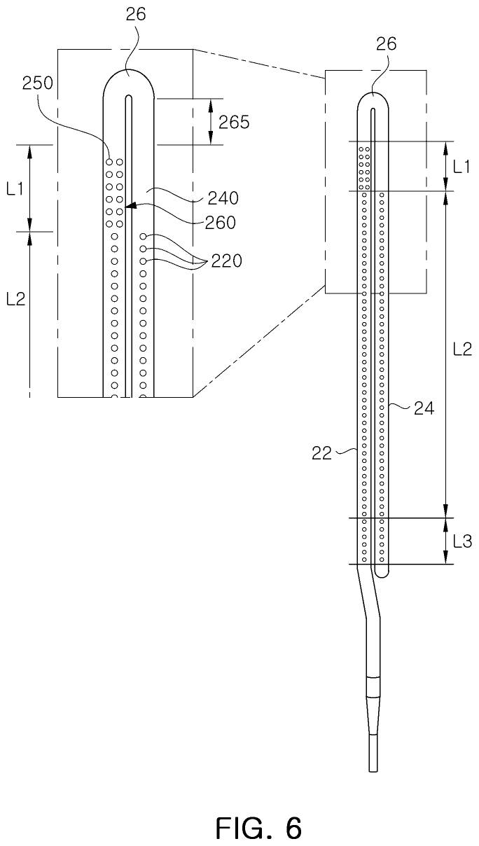

FIG. 6 is a schematic diagram of an embodiment of a source gas nozzle according to an example of the present disclosure.

In an embodiment of FIG. 6, a U-turn pipe 26 may include an extended portion 265, which may increase a flow rate discharged from the second gas discharge holes 250. The U-turn pipe 26 may include the extended portion 265, which is a gas non-discharge hole region. The extended portion 265 may be disposed in a lower region of the U-turn pipe 26. The extended portion 265 in the lower region of the U-turn pipe 26 may be disposed above the second gas discharge holes 250 in the asymmetric gas discharge hole region 260 and above the gas non-discharge hole region 240. In an embodiment, the extended portion 265 in the lower region of the U-turn pipe 26 may be disposed above the first portion L1.

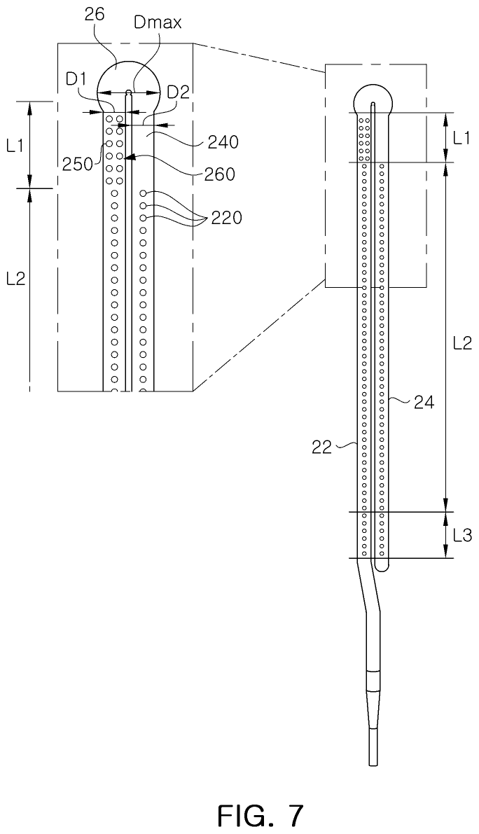

FIG. 7 is a schematic diagram of an embodiment of a source gas nozzle according to an example of the present disclosure.

In an embodiment of FIG. 7, a width of the U-turn pipe 26 may be increased. For example, a width of the U-turn pipe 26 may be greater than a width of the upstream pipe 22 or a width of the downstream pipe 24. The increased width of the U-turn pipe 26 may increase and adjust a flow rate of the source gas discharged from the second gas discharge holes 250 of the first portion L1.

In an embodiment, a maximum diameter Dmax of the U-turn pipe 26 may be greater than a sum of a diameter D1 of the upstream pipe 22 and a diameter D2 of the downstream pipe 24. The maximum diameter Dmax of the U-turn pipe 26 may be a distance between two interior opposing surfaces of the U-turn pipe 26.

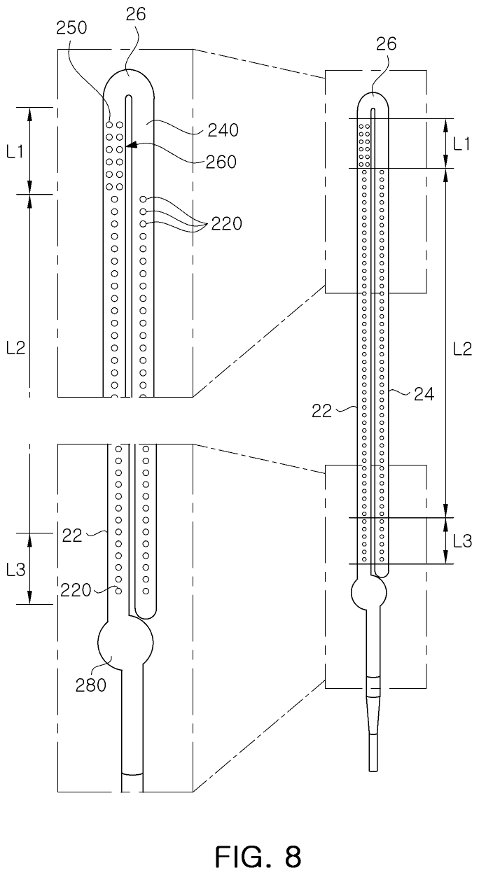

FIG. 8 is a schematic diagram of an embodiment of a source gas nozzle according to an example of the present disclosure.

In an embodiment of FIG. 8, an extension pipe 280 may be provided at a start portion of the first gas discharge holes 220 of the upstream pipe 22. The extension pipe 280 may be connected to an inlet side of the upstream pipe 22 and may be disposed below the first gas discharge holes 220 of the upstream pipe 22. The extension pipe 280 may be provided below a third portion L3 of the upstream pipe 22. The extension pipe 280 may affect a flow rate of the source gas discharged from the second gas discharge holes 250. For example, the extension pipe 280 may increase a flow rate of the source gas discharged from the second gas discharge holes 250.

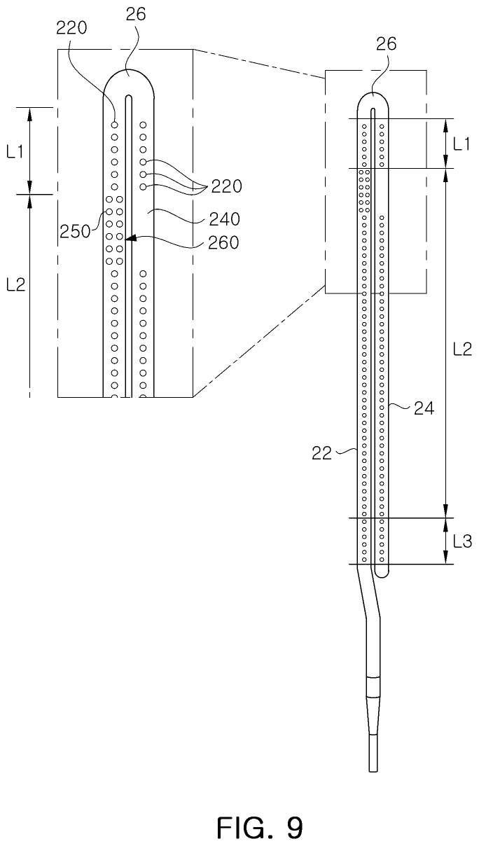

FIG. 9 is a schematic diagram of an embodiment of a source gas nozzle according to an example of the present disclosure.

In an embodiment of FIG. 9, the second gas discharge holes 250 may be disposed in a second portion L2, not in the first portion L1. The asymmetric gas discharge hole region 260 may be disposed at a position in the second portion L2 and along one of the upstream pipe 22 or the downstream pipe 24 at which a flow rate of the second gas discharge hole 250 needs to be adjusted.

The first gas discharge holes 220 may be disposed in a row in a longitudinal direction, and the second gas discharge holes 250 of the asymmetric gas discharge hole region 260 may be formed in the second portion L2 of a middle portion of the upstream pipe 22 or the downstream pipe 24, and may be disposed in multiple rows in the longitudinal direction. For example, the second gas discharge holes 250 of the asymmetric gas discharge hole region 260 may be disposed in two rows in the longitudinal direction.

In relation to the reaction tube 30 of the semiconductor wafer processing apparatus 1, the second portion L2 may correspond to a portion of the reaction tube 30 in which the process wafers Wp may be located.

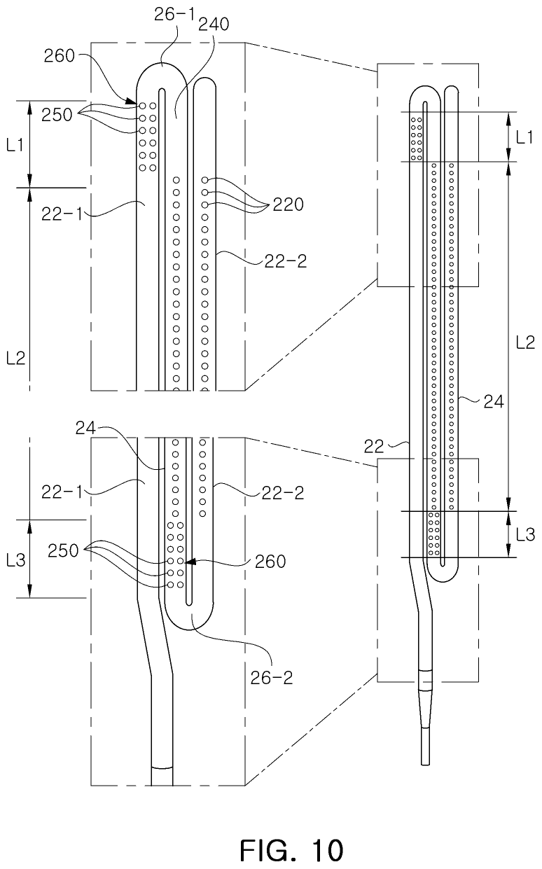

FIG. 10 is a schematic diagram of an embodiment of a source gas nozzle according to an example of the present disclosure.

Referring to an embodiment of FIG. 10, the source gas nozzle 20 may include two or more upstream pipes and one or more downstream pipes. For example, the source gas nozzle 20 may include a first upstream pipe 22-1, a second upstream pipe 22-2, a downstream pipe 24, a first U-turn pipe 26-1 and a second U-turn pipe 26-2. The first U-turn pipe 26-1 may be disposed in an upper portion and connect the first upstream pipe 22-1 to the downstream pipe 24, and the second U-turn pipe 26-2 may be disposed in a lower portion and connect the downstream pipe 24 to the second upstream pipe 22-2.

In the first upstream pipe 22-1, an asymmetric gas discharge hole region 260 comprising second gas discharge holes 250 may be disposed in multiple rows in the longitudinal direction in the first portion L1 below the first U-turn pipe 26-1. For example, the second gas discharge holes 250 may be disposed in two rows in the longitudinal direction.

In addition, the first gas discharge holes 220 may be formed in the second portion L2 of the downstream pipe 24, and the first gas discharge holes 220 may be formed in the second upstream pipe 22-2 corresponding to the second portion L2. The first gas discharge holes 220 may be omitted from the first upstream pipe 22-1 corresponding to the second portion L2.

The asymmetric gas discharge hole region 260 comprising second gas discharge holes 250 may be disposed in multiple rows in a longitudinal direction in the third portion L3 above a starting point of the second U-turn pipe 26-2. For example, the second gas discharge holes 250 may be disposed in two rows in the longitudinal direction.

In relation to the reaction tube 30 of the semiconductor wafer processing apparatus 1, the first portion L1 may be a portion at which the upper dummy wafers Wu may be located, the second portion L2 may be a portion at which the process wafers Wp may be located, and the third portion L3 may be a portion at which the lower dummy wafers W1 may be located.

The number of first gas discharge holes 220 and the number of second gas discharge holes 250 corresponding to each wafer W may be the same. For example, two gas discharge holes may correspond to each wafer W, and these two gas discharge holes per wafer may include one of the first gas discharge holes 220 disposed on each of the downstream pipe 24 the second upstream pipe 22-2, or may include two of the second gas discharge holes 250 disposed on the first upstream pipe 22-1, or may include two of the second gas discharge holes 250 disposed on the downstream pipe 24. In addition, the first portion L1, the second portion L2, and the third portion L3, may be asymmetrically maintained, having different hole patterns, while maintaining a same area of the discharge holes corresponding to each wafer W along the longitudinal direction.

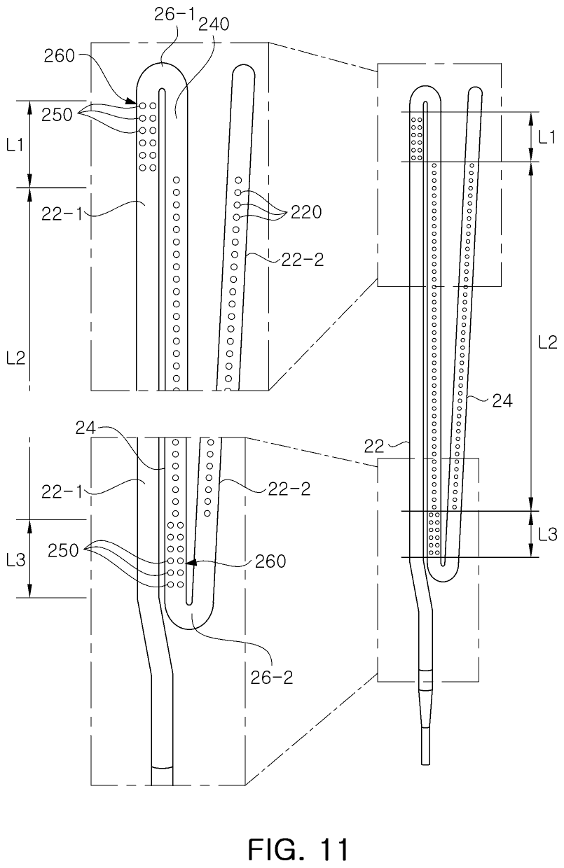

FIG. 11 is a schematic diagram of an embodiment of a source gas nozzle according to an example of the present disclosure.

Referring to an embodiment of FIG. 11, the second upstream pipe 22-2 may extend at an angle away from the longitudinal direction. For example, the second upstream pipe 22-2 extending at an angle away from the longitudinal direction may more precisely control a position and a flow rate of the source gas discharged to the wafers W. For example, the second upstream pipe 22-2 may be non-parallel with the first upstream pipe 22-1 and the downstream pipe 24, and a portion of the second upstream pipe 22-2 in the first portion L1 may be disposed away from the downstream pipe 24.

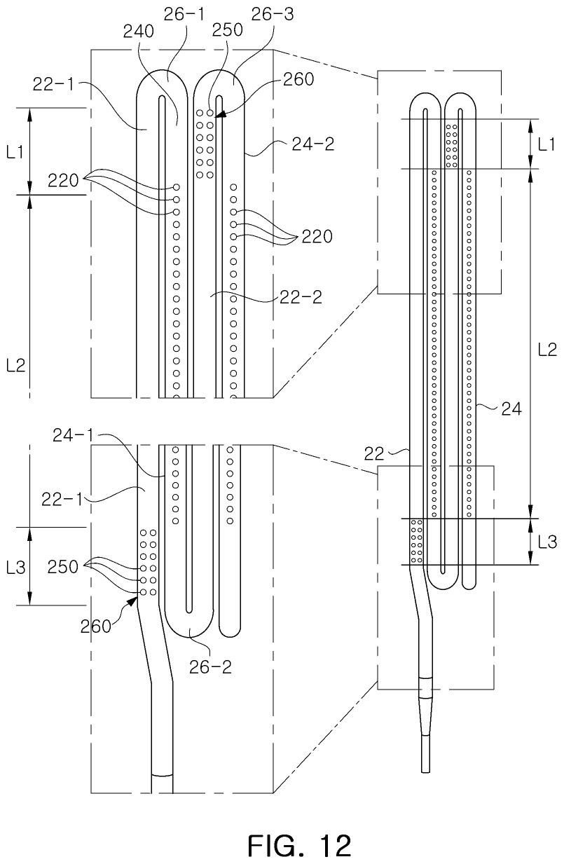

FIG. 12 is a schematic diagram of an embodiment of a source gas nozzle according to an example of the present disclosure.

Referring to an embodiment of FIG. 12, the source gas nozzle 20 may be provided with the first upstream pipe 22-1, the second upstream pipe 22-2, a first downstream pipe 24-1 and, a second downstream pipe 24-2. The first upstream pipe 22-1 may be connected to the first downstream pipe 24-1 by a first U-turn pipe 26-1, the first downstream pipe 24-1 may be connected to the second upstream pipe 22-2 by a second U-turn pipe 26-2, and the second upstream pipe 22-2 may be connected to the second downstream pipe 24-2 by a third U-turn pipe 26-3. The first U-turn pipe 26-1 and the third U-turn pipe 26-3 may be provided in an upper portion above the first portion L1, and the second U-turn pipe 26-2 may be provided in a lower portion below the third portion L3.

Asymmetric gas discharge hole regions 260, each comprising second gas discharge holes 250 disposed in rows in the longitudinal direction, may be provided in the third portion L3 on an inlet side of the first upstream pipe 22-1 and in the first portion L1 on an outlet side of the second upstream pipe 22-2. For example, the second gas discharge holes 250 may be disposed in two rows in the longitudinal direction on an inlet side of the first upstream pipe 22-1 and in two rows in the longitudinal direction on an outlet side of the second upstream pipe 22-2. The inlet side of the first upstream pipe 22-1 may receive the source gas from the gas supply pipe and the outlet side of the second upstream pipe 22-2 may supply the source gas to a third U-turn pipe 26-3.

In addition, the first gas discharge holes 220 may be disposed in the second portion L2 of the first downstream pipe 24-1 and the second downstream pipe 24-2.

In relation to the reaction tube 30 of the semiconductor wafer processing apparatus 1, the first portion L1 may be a portion at which one or more upper dummy wafers Wu may be located, the second portion L2 may be a portion at which one or more process wafers Wp may be located, and the third portion L3 may be a portion at which one or more lower dummy wafers W1 may be located.

In an embodiment, the number of first gas discharge holes 220 and the number of second gas discharge holes 250 corresponding to each wafer W may be the same. For example, two gas discharge holes disposed along the source gas nozzle 20 may correspond to each wafer W. In another example, four gas discharge holes disposed along two source gas nozzles 20 may correspond to each wafer W. In addition, the first portion L1, the second portions L2, and the third portion L3 may be asymmetrically maintained, having different hole patterns, as a whole while maintaining a same area of the discharge hole corresponding to each wafer W along the longitudinal direction.

As set forth herein, according to the source gas nozzle and semiconductor wafer processing apparatus of the present disclosure, a gas flow rate in a region corresponding to individual wafers in the reaction tube may be tuned according to a configuration of nozzle holes.

In addition, deposition layers may be uniformly formed on the wafers by controlling the flow rate of the source gas and simultaneously adjusting an amount of the source gas provided to the wafers according to a configuration of nozzle holes.

In addition, an improved source gas nozzle may be used to uniformly deposit deposition layers on a plurality of wafers and a productivity measured as a number of wafers processed per batch may be improved.

While example embodiments have been shown and described above, it will be apparent to those skilled in the art that modifications and variations could be made without departing from the scope of the present inventive concept as defined by the appended claims.

What is claimed is:

1. A source gas nozzle comprising:
an upstream pipe;
a downstream pipe; and
a U-turn pipe connecting the upstream pipe and the downstream pipe,
wherein a plurality of first gas discharge holes are disposed in a longitudinal direction along at least one of the upstream pipe or the downstream pipe,
wherein a gas non-discharge hole region and an asymmetric gas discharge hole region comprising a plurality of second gas discharge holes are disposed in opposite ones of the upstream pipe and the downstream pipe, and
wherein the gas non-discharge hole region and the asymmetric gas discharge hole region are adjacent.

2. The source gas nozzle of claim 1, wherein the plurality of first gas discharge holes are disposed in one row in the longitudinal direction, and
the plurality of second gas discharge holes are located in a first portion below the U-turn pipe and are disposed in a plurality of rows in the longitudinal direction.

3. The source gas nozzle of claim 2, wherein the plurality of second gas discharge holes comprise a plurality of first holes larger than the plurality of first gas discharge holes and a plurality of second holes smaller than the plurality of first gas discharge holes, wherein the plurality of first holes and the plurality of second holes are alternately disposed in a matrix.

4. The source gas nozzle of claim 1, wherein the U-turn pipe includes an extended portion above the gas non-discharge hole region and the asymmetric gas discharge hole region,
wherein the plurality of first gas discharge holes are disposed outside of the gas non-discharge hole region.

5. The source gas nozzle of claim 1, wherein a maximum diameter of the U-turn pipe is greater than a sum of diameters of the upstream pipe and the downstream pipe.

6. The source gas nozzle of claim 1, wherein an extension pipe is connected to an inlet side of the upstream pipe and disposed below the plurality of first gas discharge holes of the upstream pipe.

7. The source gas nozzle of claim 1, wherein the plurality of first gas discharge holes are disposed in one row extending along a length of the source gas nozzle, and
the plurality of second gas discharge holes of the asymmetric gas discharge hole region are formed in a middle portion of the upstream pipe or the downstream pipe and are disposed in two rows in the longitudinal direction.

8. The source gas nozzle of claim 1, further comprising:
a second upstream pipe; and
a second U-turn pipe connecting the downstream pipe to the second upstream pipe,
wherein the asymmetric gas discharge hole region is disposed in a first portion of the upstream pipe below the U-turn pipe,
the plurality of first gas discharge holes are disposed in the downstream pipe and the second upstream pipe in a second portion lower than the first portion, and
a second asymmetric gas discharge hole region in the downstream pipe in a third portion above the second U-turn pipe and below the second portion.

9. The source gas nozzle of claim 8, wherein the second upstream pipe extends at an angle away from the longitudinal direction.

10. The source gas nozzle of claim 1, further comprising:
a second upstream pipe;
a second downstream pipe;
a second U-turn pipe connecting the downstream pipe and the second upstream pipe; and
a third U-turn pipe connecting the second upstream pipe and the second downstream pipe,
wherein the asymmetric gas discharge hole region is disposed in a third portion on an inlet side of the upstream pipe,
the plurality of first gas discharge holes are disposed in the downstream pipe and the second downstream pipe in a second portion above the third portion, and
a second asymmetric gas discharge hole region is disposed in the second downstream pipe in a first portion below the third U-turn pipe and above the second portion.

11. A semiconductor wafer processing apparatus, comprising:
a reaction tube in which a plurality of wafers are loaded;
a gas supply pipe supplying a source gas to the reaction tube; and
a source gas nozzle disposed in the reaction tube and receiving the source gas from the gas supply pipe and spraying the source gas into the reaction tube;
wherein the source gas nozzle comprises:
an upstream pipe;
a downstream pipe; and
a U-turn pipe connecting the upstream pipe and the downstream pipe,
wherein a plurality of gas discharge holes are disposed in the source gas nozzle along the upstream pipe and the downstream pipe in an asymmetric arrangement wherein a same number of gas discharge holes of the plurality of gas discharge holes correspond to each wafer of the plurality of wafers, and
wherein at least one of the upstream pipe or the downstream pipe comprises a gas non-discharge hole region and the plurality of gas discharge holes are disposed outside of the gas non-discharge hole region.

12. The semiconductor wafer processing apparatus of claim 11, wherein the plurality of gas discharge holes comprise:
a plurality of first gas discharge holes disposed in one row a longitudinal direction; and
a plurality of second gas discharge holes disposed in an asymmetric gas discharge hole region, wherein the plurality of second gas discharge holes are disposed in a plurality of rows, wherein the asymmetric gas discharge hole region is disposed adjacent to the gas non-discharge hole region and on different ones of the upstream pipe and the downstream pipe.

13. A semiconductor wafer processing apparatus comprising:
a reaction tube;
a gas supply pipe supplying a source gas to the reaction tube; and
a source gas nozzle disposed in the reaction tube and receiving gas from the gas supply pipe and spraying the source gas into the reaction tube,
wherein the source gas nozzle comprises:
an upstream pipe;
a downstream pipe; and
a U-turn pipe connecting the upstream pipe and the downstream pipe,
wherein a plurality of first gas discharge holes are formed in a longitudinal direction in at least one of the upstream pipe or the downstream pipe,
wherein a gas non-discharge hole region in which the plurality of first gas discharge holes are not formed and an asymmetric gas discharge hole region comprising a plurality of second gas discharge holes are disposed in opposite ones of the upstream pipe and the downstream pipe, and
wherein the gas non-discharge hole region and the asymmetric gas discharge hole region are adjacent.

14. The semiconductor wafer processing apparatus of claim 13, wherein the plurality of first gas discharge holes are disposed in one row in the longitudinal direction, and
the plurality of second gas discharge holes are located in a first portion below the U-turn pipe and are disposed in two rows in the longitudinal direction.

15. The semiconductor wafer processing apparatus of claim 14, wherein the plurality of second gas discharge holes comprise a plurality of first holes larger than the plurality of first gas discharge holes and a plurality of second holes smaller than the plurality of first gas discharge holes, wherein the plurality of first holes and the plurality of second holes are alternately disposed in a matrix.

16. The semiconductor wafer processing apparatus of claim 13, wherein the U-turn pipe includes an extended portion above the gas non-discharge hole region and the asymmetric gas discharge hole region.

17. The semiconductor wafer processing apparatus of claim 13, wherein an extension pipe is connected to an inlet side of the upstream pipe and disposed below the plurality of first gas discharge holes of the upstream pipe.

18. The semiconductor wafer processing apparatus of claim 13, wherein the plurality of first gas discharge holes are disposed in one row extending along a length of the source gas nozzle, and
the plurality of second gas discharge holes of the asymmetric gas discharge hole region are formed in a middle portion of the upstream pipe or the downstream pipe and are disposed in two rows in a longitudinal direction.

19. The semiconductor wafer processing apparatus of claim 13, further comprising:
a second upstream pipe; and
a second U-turn pipe connecting the downstream pipe to the second upstream pipe,
wherein the asymmetric gas discharge hole region is disposed in a first portion of the upstream pipe below the U-turn pipe,
the plurality of first gas discharge holes are disposed in the downstream pipe and the second upstream pipe in a second portion lower than the first portion, and
a second asymmetric gas discharge hole region in the downstream pipe in a third portion above the second U-turn pipe and below the second portion.

20. The semiconductor wafer processing apparatus of claim 13, further comprising:
a second upstream pipe;
a second downstream pipe;
a second U-turn pipe connecting the downstream pipe and the second upstream pipe; and
a third U-turn pipe connecting the second upstream pipe and the second downstream pipe,
wherein the asymmetric gas discharge hole region is disposed in a third portion on an inlet side of a first upstream pipe,
the plurality of first gas discharge holes are disposed in the downstream pipe and the second downstream pipe in a second portion above the third portion, and
a second asymmetric gas discharge hole region is disposed in the second downstream pipe in a first portion below the third U-turn pipe and above the second portion.
